(19) United States
(12) Patent Application Publication
(10) Pub. No.: US 2004/0154537 A1
(43) Pub. Date: Aug. 12, 2004

(54) Diffusion furnace used for manufacturing integrated circuits and method for cooling the diffusion furnace

(76) Inventors: Choung-Ku Chon, Gyeonggi-do (KR); Dong-Hyun Choi, Gyeonggi-do (KR)

Correspondence Address: MARGER JOHNSON & McCOLLOM, P.C., 1030 S.W. Morrison Street, Portland, OR, 97205, US

(21) Appl. No.: 10/771,747

(22) Filed: Feb. 3, 2004

(30) Foreign Application Priority Data
Feb. 5, 2003 (KR) 2003-0007206

(51) Int. Cl. C23C 16/00; H01L 21/44; H01L 21/04; H01L 21/22

(52) U.S. Cl. 118/715; 118/724; 438/680; 438/542; 438/510

(57) ABSTRACT

A diffusion furnace includes a support member, a process chamber, a sealing member for sealing from the process chamber the outside, and a cooling system for cooling the sealing member. The process chamber is installed on the support member, and the sealing member is inserted between the support member and the chamber. The cooling system has a first fluid passage and a second fluid passage. The first and second fluid passages are formed in the support member. A first fluid flows in the first fluid passage to cool the sealing member, and a second fluid flows in the second fluid passage to cool the sealing member when the supply of the first fluid is interrupted. With the present invention, cooling water and a coolant can be prevented from being mixed together. Therefore, it is possible to prevent the contamination of an apparatus and the waste of expensive cooling water.

This application claims priority from Korean Patent Application No. 2003-0007206, filed on Feb. 5, 2003, the contents of which are incorporated herein by reference in their entirety.

### FIELD OF THE INVENTION

The present invention relates to an apparatus and a method for manufacturing semiconductor devices and, more particularly, to a vertical diffusion furnace which can be employed in a chemical vapor deposition (CVD) process, and to a method for cooling the vertical diffusion furnace.

### BACKGROUND OF THE INVENTION

Diffusion furnaces are used to conduct a variety of semiconductor manufacturing processes. Examples include annealing, diffusion, oxidation, and chemical vapor deposition (CVD) processes. For example, in a low pressure chemical vapor deposition (LPCVD) apparatus, a process chamber is provided having an inner tube and an outer tube which are supported by a flange located therebelow. The outer tube is disposed at the outside of the inner tube. An O-ring, which is a sealing member, is inserted between the outer tube and the flange so as to ensure effective sealing between the inside and outside of the chamber. Even though the O-ring is made of synthetic rubber which is very vulnerable to heat, the chamber is maintained at a very high temperature during the manufacturing process.

Accordingly, a typical diffusion furnace has a fluid passage disposed in a flange below the O-ring so as to prevent the O-ring from being overheated and thereby damaged by heat. The fluid passage is connected to a main supply pipe in which a coolant, such as ethylene glycol, passes. If the temperature of the coolant is too low, byproducts are deposited on an inner wall of the flange and adjacent inner sidewalls of tubes. The byproducts act as particles in subsequent processes. Hence, the temperature of the coolant is controlled by a temperature controller coupled to the main supply pipe. The coolant is then exhausted to the outside through a main exhaust pipe and returned to the temperature controller.

However, if the temperature of the coolant is not adequately controlled due to a problem in the temperature controller, the O-ring could be damaged in which in turn would cause a resultant defect during processing of the wafers, e.g., approximately 100 wafers. To overcome such a problem, an auxiliary supply pipe branching from the main supply pipe, and an auxiliary exhaust pipe branching from the main exhaust pipe, are installed. When an error occurs in the temperature controller, coolant being supplied through the main supply pipe is shut off, cooling water of about 18° C. flows to the fluid passage formed in the flange, through the auxiliary supply pipe, and is exhausted to the outside through the auxiliary exhaust pipe. The cooling water flowing to the fluid passage in the flange is mixed with coolant remaining to be exhausted to the outside through the auxiliary exhaust pipe. Further, since the ethylene glycol remaining at the fluid passage in the flange is exhausted to the outside together with the cooling water. This is a problem because high-priced ethylene glycol is wasted, and the ethylene glycol discharged is a pollutant.

### SUMMARY OF THE INVENTION

In accordance with one embodiment, the present invention provides a diffusion furnace used in fabrication of integrated circuits. The diffusion furnace includes a support member, a process chamber in which a process is carried out, a sealing member for sealing the process chamber from the outside, and a cooling system for cooling the sealing member. The process chamber is installed on the support member, and the sealing member is inserted between the flange and the chamber.

The cooling system has a first fluid passage and a second fluid passage. The first and second fluid passages are formed in the support member. A first fluid flows in the first fluid passage to cool the sealing member, and a second fluid flows in the second fluid passage to cool the sealing member when the supply of the first fluid is interrupted.

In accordance with another embodiment, the present invention provides a method for cooling a diffusion furnace. The method includes providing said diffusion furnace which includes a process chamber located on a support member, supplying a first fluid at a temperature controlled by a temperature controller to a first fluid passage formed in the support member during fabrication of said semiconductor devices, shutting off the supply of the first fluid, e.g., shutting off a first supply conduit connected to the first fluid passage when an error occurs at the temperature controller, opening a second fluid passage connected to a second fluid passage disposed in the support member to supply a second fluid to the second fluid passage, and exhausting the second fluid from the second fluid passage to the outside.

### BRIEF DESCRIPTION OF THE DRAWINGS

FIG. 1 shows a diffusion furnace according to an embodiment of the present invention.

FIG. 2 shows an example of a cooling system of FIG. 1.

FIG. 3 is a side sectional view of a flange shown in FIG. 2.

FIG. 4 shows another example of a cooling system of FIG. 1.

FIG. 5 is a side sectional view of a flange shown in FIG. 4.

FIG. 6 shows a flowchart for explaining a cooling method according to the embodiment of the present invention.

### DESCRIPTION OF THE PREFERRED EMBODIMENT

The present invention will now be described more fully hereinafter with reference to the accompanying drawings, in which preferred embodiments of the invention are shown. While the preferred embodiments relate to a low pressure chemical vapor deposition (LPCVD) apparatus acting as a diffusion furnace, they are applicable to all furnaces having a cooling system for cooling a sealing member such as an O-ring used in a process performed at a high temperature.

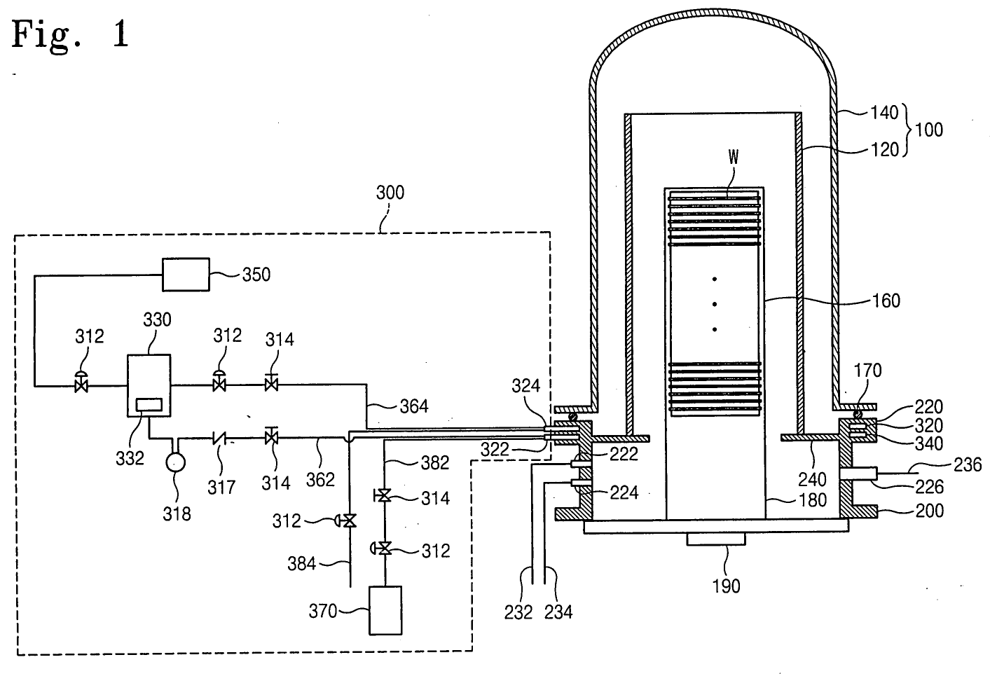

Referring to FIG. 1, a furnace includes a process chamber 100, a boat 160, a support member in the form of flange 200, a sealing member 170, and a cooling system 300.

The process chamber 100 has an inner tube 120 and an outer tube 140 which are made of quartz, in which a deposition process is carried out. The outer tube 140 surrounds the inner tube 120. The inner tube 120 and the outer tube 140 are cylindrical. A top and a bottom of the inner tube 120 are open, and only a bottom of the outer tube 140 is open. A heater (not shown) is installed outside the outer tube 140 to keep the inside of the process chamber 100 at a high temperature. A plurality of wafers W (approximately 100 wafers) are loaded on the boat 160 which is located inside the inner tube 120 and is movable up and down. An elevator 180 for enabling the boat 160 to move up and down, and a rotation unit 190 for rotating the boat 160, are installed below the boat 160. The inner tube 120 and the outer tube 140 are connected to the flange 200 and supported thereby. The sealing member 170, such as an O-ring, is inserted between the outer tube 140 and the flange 200 so as to seal the inside of the process chamber 100 from the outside.

A thru-hole is formed at the center of the flange 200. Via the thru-hole, the process chamber 100 communicates with a load-lock chamber (not shown) disposed under the flange 200. The boat 160 loads the wafers W at the load chamber and goes into and out of the process chamber 100.

The flange 200 has a supporter 220 disposed thereon to support the outer tube 140. A disk-shaped pedestal 240 extends inwardly toward an inner sidewall of the flange 200 to support the inner tube 120. A pair of process gas injection ports 222 (only one port is illustrated in FIG. 1) are connected to a process gas supply pipe 232 located at one side of the flange 200. Process gases are injected into the inner tube 120 to form a deposition layer on the wafers W loaded on the boat 160. Based on the particular process employed, additional process gas injection ports 222 may be provided. A purge gas injection port 224 is formed below the process gas injection port 222. The purge gas is, for example, nitrogen gas serving to remove air in the process chamber 100 so as to prevent formation of a native oxide layer on the wafer W. An exhaust port 226 is formed at the other side in the process chamber 100 to establish a low pressure ambient and to exhaust a gas. An exhaust line 236 is connected to the exhaust port 226.

Although the process chamber 100 is maintained at a very high temperature during a process, the O-ring 170 inserted between the supporter 220 and the outer tube 140 is made of synthetic rubber which is vulnerable to being damaged due to heating. Therefore, the diffusion furnace according to the invention has a cooling system 300 for cooling the O-ring 170 so as to prevent the O-ring 170 from being damaged by the heat.

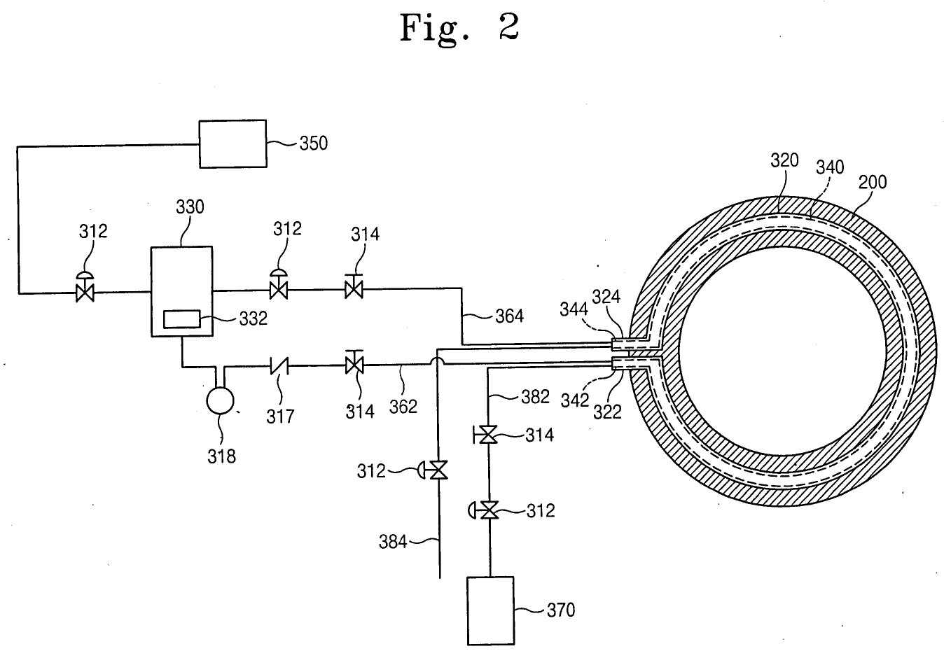

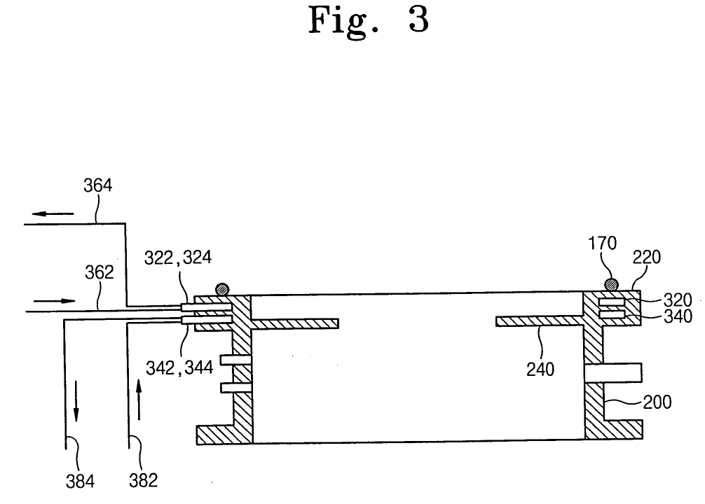

Referring to FIG. 2 and FIG. 3, cooling system 300 comprises a first fluid passage 320, a second fluid passage 340, a coolant supply pipe 362, a coolant return pipe 364, a cooling water pipe 382, a cooling water exhaust pipe 384, and a temperature controller 330.

The first fluid passage 320 is a pipe in which a first fluid, such as a coolant, flows and is disposed in the supporter 220 of the flange 200. In view of the shape of the O-ring 170, the first fluid passage 320 is substantially ring-shaped in communication with the overlying O-ring 170. A first inflow port 322 is installed at one end of the first fluid passage 320, and a first outflow port 324 is installed at the other end thereof. The coolant supply pipe 362 is connected to the first inflow port 322, and the coolant return pipe 364 is connected to the first outflow port 324. The first fluid can be selected from various kinds of coolants, but preferably is a high boiling-point fluid such as a fluid having a boiling point of at least about 200° C. Typically, an organic fluid such as ethylene glycol can be employed for this purpose. When a low-temperature coolant is provided for cooling the O-ring 170, it is possible to deposit reactive byproducts on an inner wall of the flange 200 around the first fluid passage 320. Since these reactive byproducts are employed as feed particles in a subsequent formation process, the coolant provided to the first fluid passage 320 must be kept at a suitable temperature so it will not be vaporized even at a high temperature.

The coolant supply pipe 362 is connected to the temperature controller 330 so as to control the temperature of the first fluid. The temperature controller 330 includes a heater 332 therein. The temperature of the coolant is controlled by a controller (not shown) for generally controlling an apparatus. A coolant source 350 which stores a coolant is connected to the temperature controller 330 to supply the coolant thereto. As the process proceeds, the coolant is heated to a suitable temperature. The heated coolant is supplied to the first fluid passage 320 through the coolant supply pipe 362. The coolant flows in the first fluid passage 320 to prevent the overlying O-ring 170 from being overheated and to prevent process byproducts from being deposited on the inner wall of the flange 200 adjacent to the first fluid passage 320. Thereafter, the coolant is exhausted from the first fluid passage 320 to return to the temperature controller 330 through the coolant return pipe 364.

If a problem occurs with respect to the temperature controller 330, the supplied coolant may not have a required temperature. In this case, the O-ring 170 inserted between the flange 200 and the outer tube 140 can be damaged resulting in the formation of defects in the processing of wafers W.

Therefore, the flange 200 according to this invention has a second fluid passage 340 for cooling the O-ring 170 when a problem occurs at the temperature controller 330. A second fluid flows in the second fluid passage 340. The second fluid passage 340 has a second fluid such as a coolant flowing therewithin. The second fluid passage 340 is formed below the first fluid passage 320. The second fluid passage 340 has a second inflow port 342 and a second outflow port 344 which are installed at the respective ends thereof. A cooling water supply pipe 382 is connected to the second inflow port 342, and a cooling water exhaust pipe 384 is connected to the second outflow port 344. The second fluid generally employs water as the coolant since it is low-priced and easily usable.

Since the cooling water is temporarily used before the temperature controller 330 is again placed into operation, water at a temperature of about 18° C. can continuously be supplied without a temperature controller in order to simplify the apparatus. Optionally, the cooling system can have a separate temperature controller 330 for controlling the temperature of the cooling water so that it is maintained at a constant temperature in a manner similar to the coolant.

The cooling water supply pipe 382 is connected to the cooling water source 370. Solenoid valves 312 may be installed at the coolant supply pipe 362, the coolant return pipe 364, the cooling water supply pipe 382, and the cooling water exhaust pipe 384. These solenoid valves 312 open and close a passage in response to an electrical control signal. Additionally, valves 314 and 317 may be installed to control a flow rate or prevent a backflow. A pump 318 may be connected to the coolant supply pipe 362 to provide a additional pressure to cause the fluid to flow at the requisite flow rate.

As previously stated, the first fluid passage 320 and the second fluid passage 340 are formed within the flange 200. A coolant preferably flows in the first fluid passage 320, and cooling water preferably flows in the second fluid passage 340. The coolant supplied to the first fluid passage 320 and the cooling water supplied to the second fluid passage 340 are supplied through different pipes, respectively. Thus, unlike a typical apparatus, when a higher-priced coolant and cooling water are employed, they are not mixed with each other thereby avoiding contamination of the apparatus of this invention and preventing a mixture of the coolant and the cooling water from being exhausted to the outside.

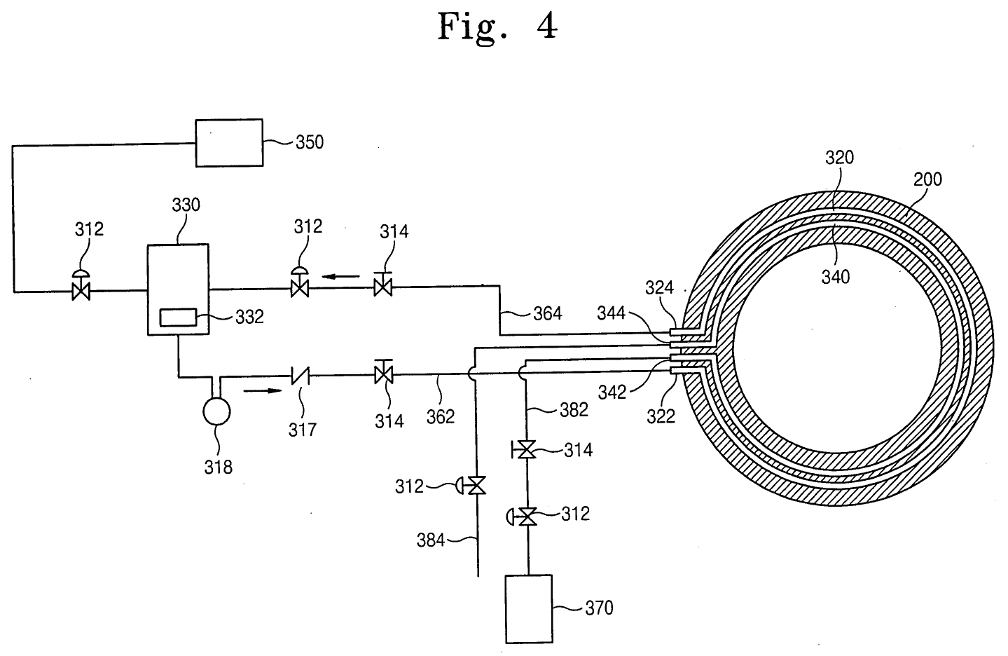

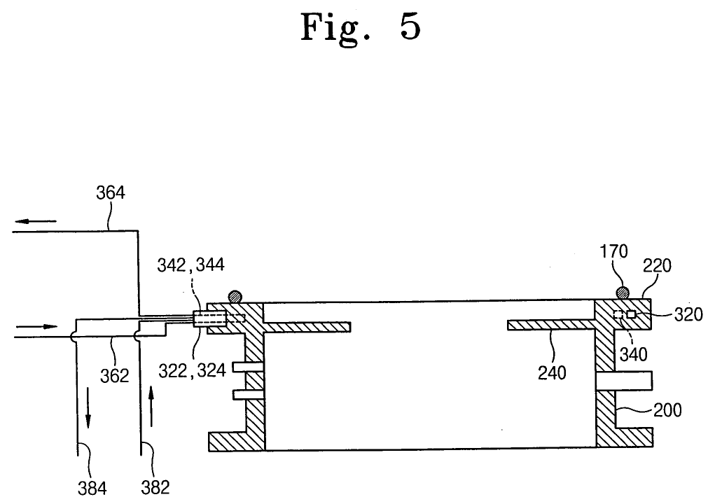

Referring to FIG. 4 and FIG. 5, a first fluid passage 320 and a second fluid passage 340 are substantially coplanar to each other and are formed within the flange 200. The second fluid passage 340 is disposed within the confines of the first fluid passage 320. The first fluid passage 320 is ring-shaped. The coolant flow within passage 320, which in communication with overlying O-ring 170, cools the O-ring. The second fluid passage 340 is also ring-shaped. It is understood that the positions of the first and second fluid passages 320 and 340 are interchangeable.

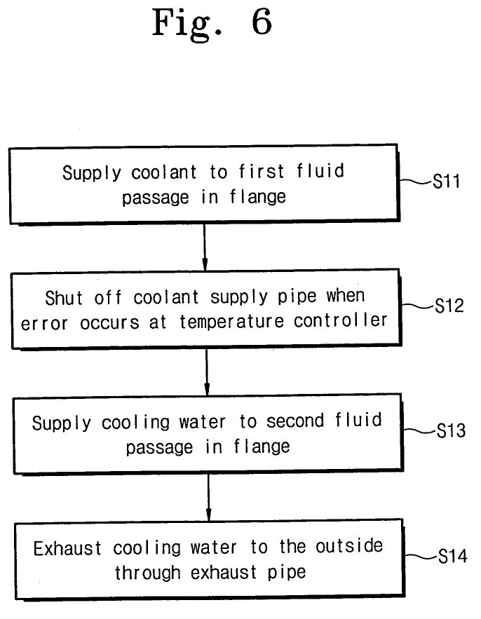

Referring to FIG. 6, in an initial state, coolant supply pipe 362 and coolant return pipe 364 are open, while cooling water supply pipe 382 and cooling water exhaust pipe 384 are closed. Coolant, which is typically ethylene glycol, is supplied from a coolant source 350 to a temperature controller 330. Using a heater 332 located in the temperature controller 330, the ethylene glycol is controlled so that it has a substantially constant temperature. The ethylene glycol flows in a first fluid passage 320 formed in a supporter 220 of a flange 200 through the coolant supply pipe 362 to cool O-ring 170, and to prevent deposition of reactive byproducts on an inner wall of the flange 200 where the first fluid passage 320 is formed. The ethylene glycol flowing in the first fluid passage 320 returns to the temperature controller 330 through a cooling water return pipe 364 (S11). When an error occurs at the temperature controller 330 during a process, the coolant supply pipe 362 and the coolant return pipe 364 are shut off (S12). The cooling water supply pipe 382 and the cooling water exhaust pipe 384 are then opened, and the cooling water of about 18° C. flows from a cooling water source 370 to the second fluid passage through the cooling water supply pipe 382 to cool the O-ring 170 (S13). The cooling water from the second fluid passage 340 is exhausted to the outside through the cooling water exhaust pipe 384 (S14). If the temperature controller 330 is operating in a predetermined conventional mode, the controller shuts off the cooling water supply pipe 382 and the cooling water exhaust pipe 384, and re-opens the coolant supply pipe 362 and the coolant return pipe 384 to cool the O-ring 172 employing the coolant flowing in the first fluid passage 320.

While the invention has been illustrated and described in detail in the foregoing drawings and description, the same is to be considered as illustrative and not restrictive in character, it being understood that only preferred embodiments thereof have been shown and described and that all changes and modifications that come within the spirit of the invention are desired to be protected.

What is claimed is:

1. A diffusion furnace for use in fabricating semiconductor devices, the furnace comprising:
a support member;
a process chamber installed on the support member;
a sealing member for sealing the process chamber from the outside, the sealing member being inserted between the support member and the process chamber; and
a cooling system for cooling the sealing member, the cooling system including a first fluid passage in which a first fluid flows for cooling the sealing member, the first fluid passage being formed within the support member, and a second fluid passage in which a second fluid flows for cooling the sealing member when supplying the first fluid is interrupted, the second fluid passage being formed within the support member.

2. The diffusion furnace of claim 1, wherein the cooling system includes:
a first supply conduit connected to a first inflow port formed at one end of the first fluid passage;
a return conduit connected to a first outflow port formed at the other end of the first fluid passage;
a temperature controller, to which the first supply conduit and the return conduit are connected, for controlling the temperature of the first fluid supplied to the first supply conduit;
a second supply conduit connected to a second inflow port formed at one end of the second fluid passage; and
an exhaust conduit connected to a second outflow port formed at the other end of the second fluid passage.

3. The diffusion furnace of claim 1, wherein the sealing member is an O-ring.

4. The diffusion furnace of claim 1, wherein the first and second fluid passages are substantially ring-shaped.

5. The diffusion furnace of claim 4, wherein the second fluid passage is formed substantially coplanar with the first fluid passage.

6. The diffusion furnace of claim 4, wherein the first fluid passage and the second fluid passage are disposed one over the other.

7. The diffusion furnace of claim 1, wherein the first fluid has a higher boiling point than the second fluid.

8. The diffusion furnace of claim 1, wherein the second fluid is cooling water.

9. The diffusion furnace of claim 1, wherein the first fluid is an organic liquid.

10. The diffusion furnace of claim 1, wherein the first fluid is ethylene glycol.

11. A method for cooling a diffusion furnace, the method comprising:
providing said diffusion furnace which includes a process chamber located on a support chamber;
supplying a first fluid at a temperature controlled by a temperature controller to a first fluid passage formed in the support member;
shutting off a first supply pipe connected to the first fluid passage when an error occurs at the temperature controller; and
opening a second fluid passage connected to a second fluid passage disposed in the flange to supply a second fluid to the second fluid passage.

12. The method of claim 11, further comprising exhausting the second fluid from the second fluid passage to the outside.

13. The method of claim 11, wherein the second fluid is cooling water.

14. The method of claim 11, wherein the first fluid is glycol.

15. The method of claim 11, wherein the first and second fluid passages are substantially ring-shaped.

16. The method of claim 11, wherein the second fluid passage is formed substantially coplanar with the first fluid passage.

17. The method of claim 11, wherein the first fluid passage and the second fluid passage are disposed one over the other.

18. A method for cooling a diffusion furnace for fabricating semiconductor devices, the method comprising:
providing said diffusion furnace which includes a process chamber located on a support member;
supplying a first fluid at a temperature within a predetermined temperature range to a first fluid passage formed within said support member for cooling said support member during fabrication of said semiconductor devices;
shutting off the supply of the first fluid when the temperature of the first fluid is outside the predetermined temperature range; and
supplying a second fluid to a second fluid passage within the support member for cooling the support member to a temperature within the predetermined temperature range.

19. The method of claim 18, which further includes providing a sealing member, and sealing said process chamber from the outside with said sealing member.

20. The method of claim 18, wherein the sealing member comprises an O-ring.

21. The method of claim 18, which further comprises exhausting the second fluid from the second fluid passage to the outside.

22. The method of claim 18, wherein the second fluid passage is formed substantially coplanar with the first fluid passage.

23. The method of claim 18, wherein the first fluid passage and the second fluid passage are disposed one over the other.
